(19) United States
(12) Patent Application Publication
(10) Pub. No.: US 2025/0218653 A1
(43) Pub. Date: Jul. 3, 2025

(54) MAGNETIC FLUX SHIELDING FOR HIGH ENERGY INDUCTORS

(71) Applicant: NVIDIA CORPORATION, Santa Clara, CA (US)

(72) Inventor: Lizhi ZENG, Shenzhen, Guangdong (CN)

(21) Appl. No.: 18/262,001

(22) PCT Filed: Jun. 25, 2023
(86) PCT No.: PCT/CN2023/102160

§ 371 Date: Jul. 18, 2023

(51) Int. Cl. H01F 27/36; H01F 27/29; H05K 1/18

(52) U.S. Cl. CPC H01F 27/363; H01F 27/292; H05K 1/181; H05K 2201/1003

(57) ABSTRACT

In various embodiments, an inductor package comprising an inductor that produces a first magnetic flux, and a conductive material disposed on the inductor that provides a reflective magnetic flux that at least partially cancels the first magnetic flux. Other embodiments include a circuit board comprising a printed circuit board (PCB); and at least one inductor package fixed to the PCB, the inductor package including an inductor that produces a first magnetic flux, and a conductive material shielding disposed over at least a portion of a surface of the inductor that provides a reflective magnetic flux that at least partially cancels the first magnetic flux.

### BACKGROUND

### Field of the Various Embodiments

The various embodiments relate generally to computer systems and electrical circuits and, more specifically, to magnetic flux shielding for high energy inductors.

### Description of the Related Art

Computer devices and systems typically include various electronic circuits to regulate the power delivered to components within those devices and systems when performing tasks. For example, various computing devices include multiple power control circuits, such as boost converters and buck converters. Computing devices typically also include circuits including a combination of resistors (R), inductors (L), and capacitors (“RLC circuits”) for other applications, including controlling oscillations, filtering, and tuning, to name a few. When designing electronic circuits, designers attempt to minimize the form factor of the components making up the electronic circuits, such as the inductors included in a RLC circuit. However, high-performance computer devices, such as laptops, desktops, motherboards, and graphical processing units (GPUs), consume large amounts of power and therefore require large inductors with high current ratings to control the power drawn by those devices during operation. Consequently, designers oftentimes select inductors with high-current ratings and small form factors for use in these types of devices.

In order to meet the constraints of both a high current rating and a small form factor, designers typically select inductors made with low magnetic permeability materials, such as iron alloys. This group of materials has characteristics, such as high saturation and fast response time (where smaller inductance in a switching power circuit enables faster response times), that allow the inductor to effectively carry a high current. However, one characteristic of low magnetic permeability material is that inductors made from such materials can have substantial magnetic flux leakage that can cause electromagnetic interference problems with other electronic components within a computer device or system or make the device fail to meet electromagnetic compatibility (EMC) regulatory requirements, as the electromagnetic interference caused by the flux leakage can spread to other components or devices via connected power lines or communication lines. As a result, sufficient distances between the inductors and the other electronic components, as well as additional materials added to the other electronic components, such as absorbent material or metal covers, within the computer device or system have to be incorporated into designs, which can undesirably increase form factors when using inductors made with low magnetic permeability materials.

Conventional approaches to addressing magnetic flux leakage issues include adding metal shielding around inductors, which reduces the amount of magnetic flux emanating from inductor packages and reduces the spacing required to mitigate the magnetic flux interference problems with the other electronic components within a computer device or system. However, one drawback of using metal shielding is that conventional metal shielding typically has substantial thickness, which enlarges the overall size of each inductor package. The large inductor packages limit the density and types of inductors that can be included within the area of a printed circuit board. Further, the metal shielding normally is not “airtight” and can include gaps. Those gaps can reduce the effectiveness of the metal shielding due to magnetic flux leakage that can emanate from the gaps. Some solutions have incorporated overlapping layers to eliminate the gaps; however, overlapping layers adds more thickness to portions of the inductor packages, further increasing the overall size of the inductor package.

As the foregoing illustrates, what is needed in the art are more effective designs for inductors used in computer devices and systems.

### SUMMARY

In various embodiments, an inductor package comprising an inductor that produces a first magnetic flux, and a conductive material disposed on the inductor that provides a reflective magnetic flux that at least partially cancels the first magnetic flux.

Other embodiments include a circuit board comprising a printed circuit board (PCB); and at least one inductor package fixed to the PCB, the inductor package including an inductor that produces a first magnetic flux, and a conductive material shielding disposed over at least a portion of a surface of the inductor that provides a reflective magnetic flux that at least partially cancels the first magnetic flux.

At least one technical advantage of the disclosed design relative to the prior art is that, with the disclosed design, the inductor package includes the conductive plating or conductive paint that has less thickness than the metal shielding used in conventional designs. Further, the conductive plating or conductive paint implemented with the disclosed design can reduce or eliminate the gaps oftentimes seen with conventional metal shielding, thereby limiting the magnetic flux that leaks from the inductors within the inductor packages. Consequently, the disclosed design enables a given printed circuit board to include a higher density of inductors relative to what can be achieved using conventional designs, thereby improving the ability to control power use in high-performance computer devices and systems and with high-performance applications.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 illustrates an inductor package that includes metal plate shielding, according to the prior art.

FIG. 2 is a conceptual diagram of a portion of conductive material inhibiting a portion of magnetic flux produced by an inductor, according to various embodiments.

FIG. 3 illustrates an example inductor package that includes conductive material, according to various embodiments.

FIG. 4 illustrate graphs of the magnetic fluxes produced by two types of inductor packages, according to various embodiments.

FIG. 5 compares the inductor package of FIG. 3 with an inductor package of another embodiment.

FIG. 6 illustrates a circuit board that includes one or more inductor packages, according to various embodiments.

FIG. 7 is a block diagram of a computer system configured to implement one or more aspects of the present invention.

### DETAILED DESCRIPTION

In the following description, numerous specific details are set forth to provide a more thorough understanding of the various embodiments. However, it will be apparent to one skilled in the art that the inventive concepts may be practiced without one or more of these specific details.

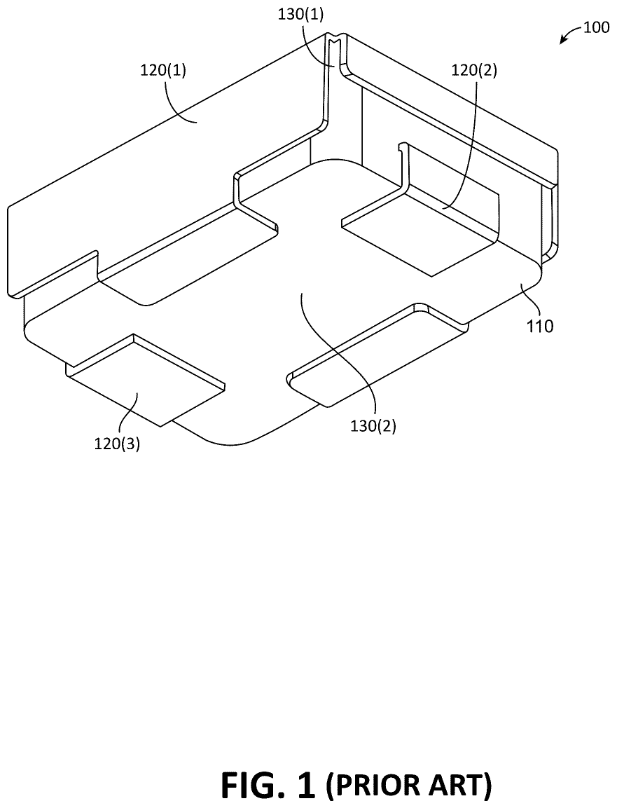

FIG. 1 illustrates an inductor package 100 that includes metal plate shielding, according to the prior art. As shown the inductor package 100 includes an inductor 110, metal plates 120 (e.g., 120(1), 120(2), 120(3), etc.), and gaps 130 (e.g., 130(1), 130(2), etc.).

In operation, one or more metal plates 120 are applied to the exterior of the inductor 110. In some examples, the core of the inductor 110 is a rod-like or drum-like core. As a result, when current flows through the inductor 110, magnetic flux flows out of the core, creating a leakage magnetic flux that emanates from the inductor 110. The portions of the metal plates 120 attenuate the leakage magnetic flux, mitigating the interference to other components. Other shapes for the core of the inductor 110 are possible. For example, the core of the inductor 110 can be a toroid, a block, etc. In such instances, the metal plates are applied to inductor package based on the magnetic field produced by the inductor 110.

The metal plates 120 are ferromagnetic metals, such as metal alloys containing iron or cobalt that enable the metal plates to be electrically conductive. Such materials absorb and reflect the magnetic fields and associated magnetic flux generated by the inductor 110. To provide sufficient reflective magnetic fields counteract the flux leakage associated with the magnetic field generated by the inductor 110, the metal plates 120 require a minimum thickness based on the characteristics of the inductor 110. For example, the metal plates 120(1)-120(3) have a 0.5 mm thickness to shield magnetic field intensity and associated magnetic flux created by the inductor 110. As a result, the thickness of the metal plates 120(1)-120 (3) adhered to the surface of the inductor 110 increases each dimension of the inductor package 100, increasing the size of the inductor package 100 on printed circuit boards. Consequently, the metal plates 120 lower the density of inductor packages 100 relative to other inductors that can fit on a printed circuit board.

In some examples, the metal plates 120 do not provide airtight coverage, causing the inductor package 100 to include one or more gaps 130 that expose portions of the inductor 110. In operation, some magnetic flux emanates from the gaps 130, limiting the overall effectiveness of the metal plates 120. In some examples (not shown), one or more additional overlapping plates are added during the fabrication process to eliminate the gaps 130. The overlapping plates increase the effectiveness of the magnetic flux shielding provided by the metal plates 120, yet further increase the size of the inductor package 100.

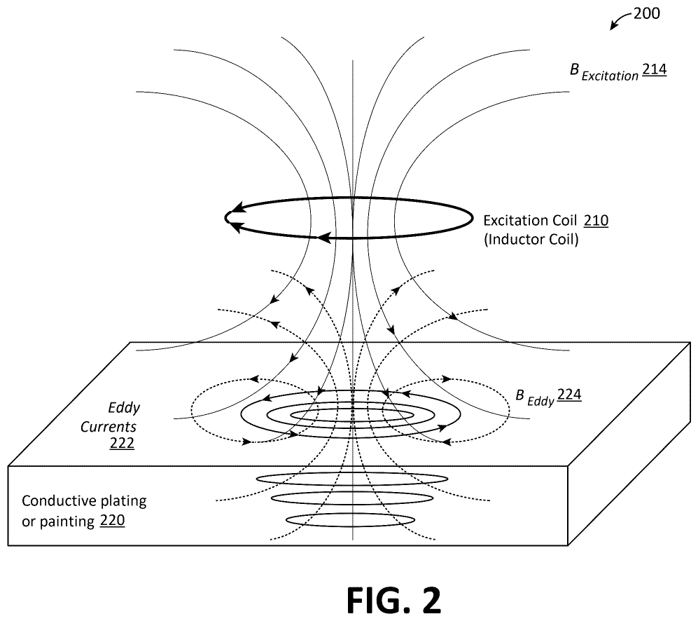

FIG. 2 is a conceptual diagram of a portion of conductive material inhibiting a portion of magnetic flux produced by an inductor, according to various embodiments. As shown, and without limitation, a portion of inductor package 200 includes an excitation coil (inductor coil) 210, a conductive material 220 (e.g., conductive plating or conductive paint), an excitation field 214, one or more eddy currents 222, and an eddy field 224.

In operation, the inductor coil 210 generates magnetic field as the excitation field 214, where an excitation flux is based on the excitation field 214. The excitation field 214 induces multiple eddy currents 222 in the conductive material 220. The eddy currents 222 also generate a magnetic field as the eddy field 224 having an associated magnetic flux. The eddy field 224 reflects the excitation field 214, reducing the amount of excitation field 214 that emanates through the conductive material. In such instances, the magnetic flux of the associated eddy field reflects at least a portion of the magnetic flux that is associated with the excitation field 214

In various embodiments, the conductive material 220 is conductive plating that covers significant portions of the inductor 110. For example, the types of material for the conductive plating can include gold, silver, copper, nickel and/or alloys that are plated to the inductor 110 during fabrication. Alternatively, in some embodiments, the conductive material 220 is a conductive paint that is electrically conductive. For example, the conductive paint can include a conductive pigment, such as silver, copper, nickel, or carbon (e.g., conductive carbon, graphite, etc.), that is suspended as particles in a solution or dissolved in a solution. In some embodiments, the conductive paint can include specific material properties (e.g., electrical conductivity, morphology, corrosion resistance, etc.) for a specific application. For example, conducive acrylic paints also provide electromagnetic interference (EMI) and radio frequency interference (RFI) protection for plastic objects.

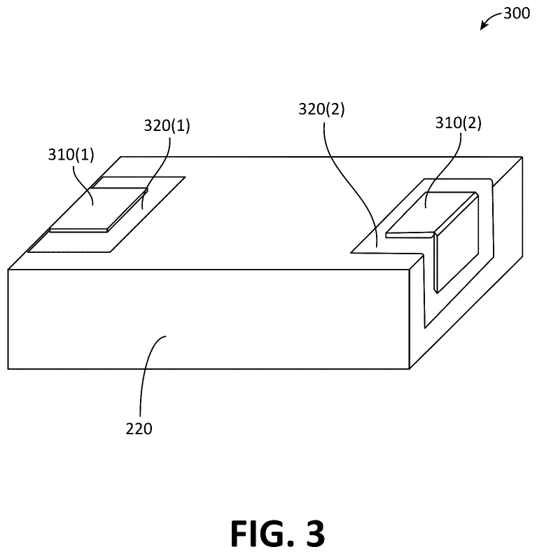

FIG. 3 illustrates an example inductor package 300 that includes conductive material 220, according to various embodiments. As shown, and without limitation, the inductor package includes the conductive material 220, connection pins 310 (e.g., 310(1), 310(2), etc.) and clearance areas 320 (e.g., 320(1), 320(2), etc.).

In operation, the conductive material 220 is applied to the inductor 110 (not shown), with clearance areas 320 covering the remaining in portions of the inductor 110. In some embodiments, one or more sets of connection pins 310 are added within the clearance areas 320. The connection pins 310 are disposed directly on the inductor 110 and enable the inductor 110 of the inductor package 300 to electrically connect to other electronic components.

During fabrication, the conductive material 220 is applied to one or more surfaces of the inductor 110. For example, the conductive paint is applied via spraying or brushing to each surface of the inductor 110. In this manner, the conductive material 220 comprising the conductive paint covers larger portions of the inductor 110, reducing potential gaps of the inductor package 300 to only the designed clearance areas 320.

In some embodiments, the conductive material 220 is a conductive plating that is applied via electroplating. In some embodiments, the surface of the inductor 110 is metallized during fabrication. For example, the inductor 110 can be metallized via vacuum coating, metal spraying, cathode sputtering, chemical deposition, etc. Once metallized, the inductor 110 is coated with a layer of conductive metal film on the surface of inductor 110 (excluding the clearance areas 320, which are masked). An electroplating process applies the conductive plating over the conductive metal film, coating the conductive metal film with the conductive plating.

In some embodiments, the thickness of the conductive plating and/or additional layers of the conductive paint can be applied to adjust the amount of magnetic flux shielding that the conductive material 220 provides. For example, the conductive material 220 can have a thickness of 5 μm to 0.2 mm based on the characteristics of the inductor 110.

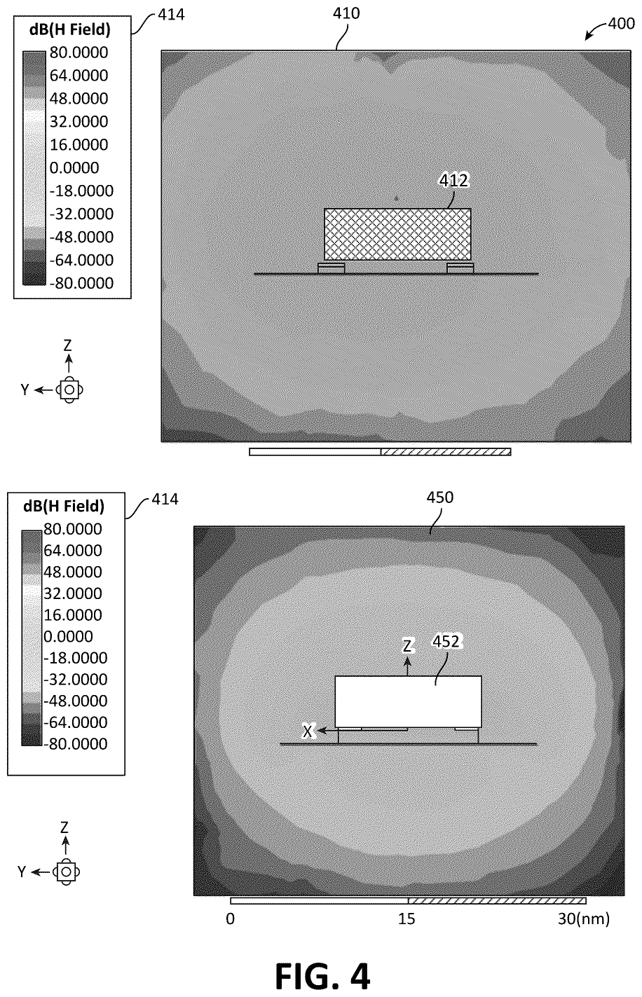

FIG. 4 illustrate graphs 400 of the magnetic fluxes produced by two types of inductor packages, according to various embodiments. As shown, and without limitation, the graphs 400 include a magnetic flux graph 410 for an unshielded inductor package 412 and a magnetic flux graph 450 for a shielded inductor package 452.

The magnetic flux graph 410 is a simulation of the unshielded inductor package 412 when producing a magnetic field. As shown, the unshielded inductor package 412 produces a magnetic field and associated magnetic flux whose intensity dissipates over distance from the inductor package 412. As indicated by the legend 414, the unshielded inductor package 412 initially produces a magnetic field with a magnetic field intensity (H) of 16 dB, gradually dissipating to −48 dB a distance away from the inductor package 412.

The magnetic flux graph 410 is a simulation of the shielded inductor package 452 in operation. As shown, the unshielded inductor package 412 produces a magnetic field and associated magnetic flux whose intensity dissipates over distance from the inductor package 452. As indicated by the legend 414, the shielded inductor package 452 has emits a magnetic field with a smaller initial magnetic field intensity (H) of 0 dB, gradually dissipating to −80 dB at greater distances. The conductive material 220 in the inductor package 452, which is applied to the surface of the inductor 110, thus provides shielding of approximately 16 dB to the magnetic field intensity of the magnetic field, indicating an increased effectiveness in the magnetic flux shielding that the conductive material 220 applies.

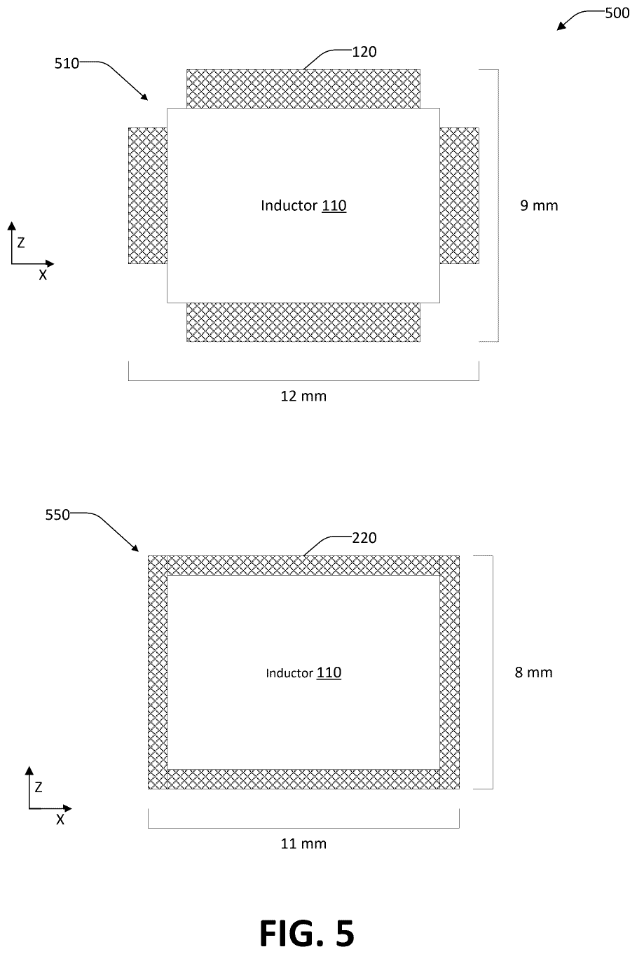

FIG. 5 compares the inductor package of FIG. 3 with an inductor package of another embodiment. As shown, and without limitation, the metal shielded inductor package 510 includes the inductor 110 and metal plates 120. As shown, and without limitation, the conductive material shielded inductor package 550 includes the inductor 110 and conductive material 220.

View 500 illustrates a top view of inductor packages 510, 550 that respectively shield an inductor 110. The inductor 110 is packaged in a manner where the core and coils are housed in an enclosure that is 7 mm by 10 mm. The metal shielded inductor package 510 occupies a 9 mm by 12 mm area (108 mm²) due to the 1 mm metal plates 120 applied to each side of the inductor 110. By way of contrast, the conductive material shielded inductor package 550 is similar to the inductor packages 300, 452 and occupies a smaller 8 mm by 11 mm area (88 mm²) due to the conductive material 220, which is 0.5 mm thinner than the metal plates 120, being applied to each side of the inductor 110. As a result, a printed circuit board can include a greater density of the conductive material shielded inductor packages 550.

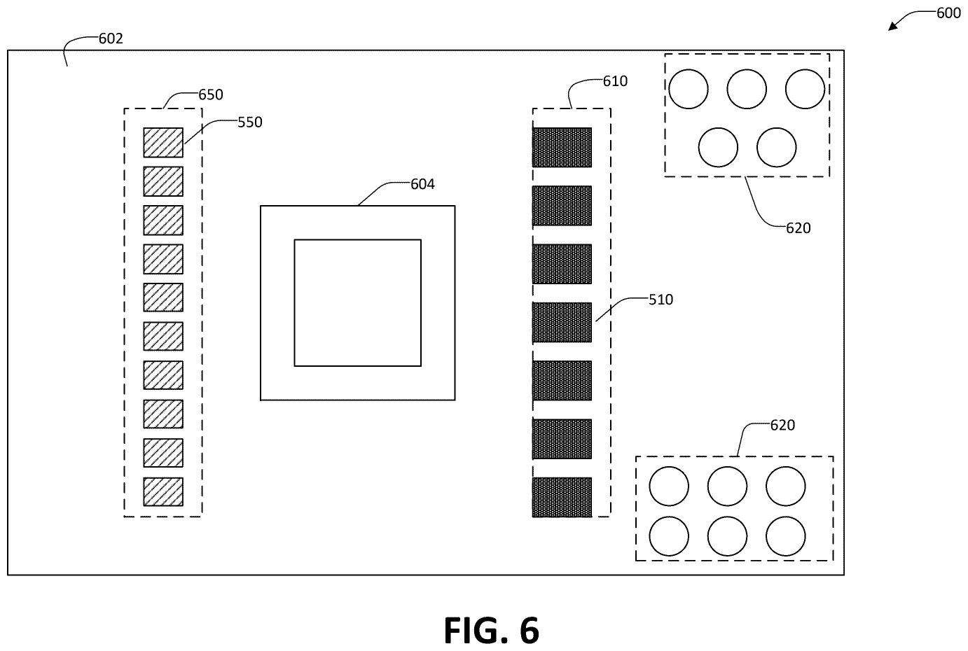

FIG. 6 illustrates printed a circuit board (PCB) assembly 600 that includes one or more inductor packages, according to various embodiments. As shown, and without limitation, the PCB assembly 600 includes a PCB layer 602, a central processing unit (CPU) 604, capacitor banks 620 a first inductor area 610, a set of metal shielded inductor packages 510, a second inductor area 650, and a set of conductive material shielded inductor packages 550.

The PCB assembly 600 is designed to connect a large quantity of electronic components to perform various tasks. As persons skilled in the art will understand, the disclosed designs can be used with any inductor, including inductor 110, and, therefore, can be used across a wide variety of applications, including, and without limitation, various types of desktops, laptops, workstations, servers, medical devices, automotive devices, and/or robots. The conductive material 220 is added to one or more electronic components of the PCB assembly 600 (e.g., the set of conductive material shielded inductor packages 550) to reduce the internal magnetic flux interference, magnetic flux interference between electronic components, and/or magnetic flux interference between the PCB assembly 600 and other devices.

As shown, the inductors and capacitors of the PCB assembly 600 can be separately connected as separate oscillators, filters, switching power circuits (boost converters, buck converters, boost/buck converters, inverters, etc.), and so forth. The PCB assembly 600 includes two equally sized inductor areas 610, 650. While the first inductor area 610 includes seven metal shielded inductor packages 510, the second inductor area 650 includes ten conductive material shielded inductor packages 550. As the inductors 110 in each of the respective inductor packages 510, 550 are the same type, the additional density of the conductive material shielded inductor packages 550 within the second inductor area 650 improves the ability to control power use on the PCB assembly 600.

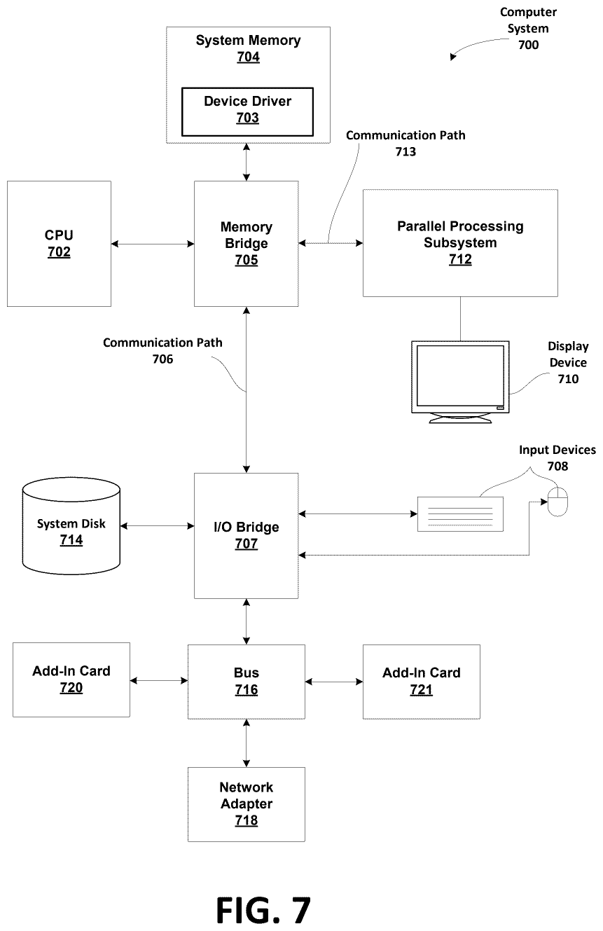

FIG. 7 is a block diagram of a computer system configured to implement one or more aspects of the present invention. As shown, computer system 700 includes, without limitation, a central processing unit (CPU) 702 and a system memory 704 coupled to a parallel processing subsystem 712 via a memory bridge 705 and a communication path 713. Memory bridge 705 is further coupled to an I/O (input/output) bridge 707 via a communication path 706, and I/O bridge 707 is, in turn, coupled to a bus 716.

In various embodiments, one or more components of the computer system 700 (e.g., the CPU 702, the parallel processing subsystem 712, etc.) includes one or more circuit boards that incorporate one or more of the conductive material shielded inductor packages 550 as part of the circuitry. For example, a circuit board containing the CPU 702 can include one or more switching power circuits that include at least one conductive material shielded inductor package 550.

In operation, I/O bridge 707 is configured to receive user input information from input devices 708, such as a keyboard or a mouse, and forward the input information to CPU 702 for processing via communication path 706 and memory bridge 705. Bus 716 is configured to provide connections between I/O bridge 707 and other components of the computer system 700, such as a network adapter 718 and various add-in cards 720 and 721.

As also shown, I/O bridge 707 is coupled to a system disk 714 that may be configured to store content and applications and data for use by CPU 702 and parallel processing subsystem 712. As a general matter, system disk 714 provides non-volatile storage for applications and data and may include fixed or removable hard disk drives, flash memory devices, and CD-ROM (compact disc read-only-memory), DVD-ROM (digital versatile disc-ROM), Blu-ray, HD-DVD (high definition DVD), or other magnetic, optical, or solid state storage devices. Finally, although not explicitly shown, other components, such as universal serial bus or other port connections, compact disc drives, digital versatile disc drives, film recording devices, and the like, may be connected to I/O bridge 707 as well.

In various embodiments, memory bridge 705 may be a Northbridge chip, and I/O bridge 707 may be a Southbrige chip. In addition, communication paths 706 and 713, as well as other communication paths within computer system 700, may be implemented using any technically suitable protocols, including, without limitation, AGP (Accelerated Graphics Port), HyperTransport, or any other bus or point-to-point communication protocol known in the art.

In some embodiments, parallel processing subsystem 712 comprises a graphics subsystem that delivers pixels to a display device 710 that may be any conventional cathode ray tube, liquid crystal display, light-emitting diode display, or the like. In such embodiments, the parallel processing subsystem 712 incorporates circuitry optimized for graphics and video processing, including, for example, video output circuitry. As described in greater detail below in FIG. 2, such circuitry may be incorporated across one or more parallel processing units (PPUs) included within parallel processing subsystem 712. In other embodiments, the parallel processing subsystem 712 incorporates circuitry optimized for general purpose and/or compute processing. Again, such circuitry may be incorporated across one or more PPUs included within parallel processing subsystem 712 that are configured to perform such general purpose and/or compute operations. In yet other embodiments, the one or more PPUs included within parallel processing subsystem 712 may be configured to perform graphics processing, general purpose processing, and compute processing operations. System memory 704 includes at least one device driver 703 configured to manage the processing operations of the one or more PPUs within parallel processing subsystem 712. The system memory 704 also includes any number of software applications 725 that execute on the CPU 702 and may issue commands that control the operation of the PPUs.

In various embodiments, parallel processing subsystem 712 may be integrated with one or more other the other elements of FIG. 1 to form a single system. For example, parallel processing subsystem 712 may be integrated with CPU 702 and other connection circuitry on a single chip to form a system on chip (SoC).

It will be appreciated that the system shown herein is illustrative and that variations and modifications are possible. The connection topology, including the number and arrangement of bridges, the number of CPUs 702, and the number of parallel processing subsystems 712, may be modified as desired. For example, in some embodiments, system memory 704 could be connected to CPU 702 directly rather than through memory bridge 705, and other devices would communicate with system memory 704 via memory bridge 705 and CPU 702. In other alternative topologies, parallel processing subsystem 712 may be connected to I/O bridge 707 or directly to CPU 702, rather than to memory bridge 705. In still other embodiments, I/O bridge 707 and memory bridge 705 may be integrated into a single chip instead of existing as one or more discrete devices. Lastly, in certain embodiments, one or more components shown in FIG. 7 may not be present. For example, bus 716 could be eliminated, and network adapter 718 and add-in cards 720, 721 would connect directly to I/O bridge 707.

In sum, a conductive material is applied to one or more portions of an inductor to provide magnetic flux shielding for an inductor package, reducing magnetic flux leakage that emanates from the inductor package into an environment. The conductive material can be a conductive paint that is applied to one or more surfaces of the inductor. Alternatively, the conductive material can be a conductive plating that is applied via electroplating to the surfaces of the inductor. The conductive material is a material with high magnetic permeability that produces a magnetic flux that at least partially reflects a magnetic flux generated by the inductor coil during excitation. When the conductive shielding produces the reflective magnetic flux, the magnetic flux emanates from the inductor package. The reduced magnetic flux results in a reduced amount of spacing required between the inductor package and other electronic and electrical components.

At least one technical advantage of the disclosed design relative to the prior art is that, with the disclosed design, the inductor package includes the conductive plating or conductive paint that has less thickness than the metal shielding used in conventional designs. Further, the conductive plating or conductive paint implemented with the disclosed design can reduce or eliminate the gaps oftentimes seen with conventional metal shielding, thereby limiting the magnetic flux that leaks from the inductors within the inductor packages. Consequently, the disclosed design enables a given printed circuit board to include a higher density of inductors relative to what can be achieved using conventional designs, thereby improving the ability to control power use in high-performance computer devices and systems and with high-performance applications.

1. In various embodiments, an inductor package comprises an inductor that produces a first magnetic flux, and a conductive material disposed on the inductor that provides a reflective magnetic flux that at least partially cancels the first magnetic flux.

2. The inductor package of clause 1, where the conductive material comprises a conductive paint applied to at least a portion of a surface of the inductor.

3. The inductor package of clause 1 or 2, where the conductive paint comprises a conductive pigment containing at least one of silver, copper, nickel, conductive carbon, or graphite.

4. The inductor package of any of clauses 1-3, where the conductive material comprises a conductive plating applied to at least a portion of a surface of the inductor via electroplating.

5. The inductor package of any of clauses 1-4, where the conductive plating comprises a material containing at least one of gold, silver, copper, or nickel.

6. The inductor package of any of clauses 1-5, where the conductive material has a thickness of 5 μm to 0.2 mm on at least a portion of a surface of the inductor.

7. The inductor package of any of clauses 1-6, where a least a portion of a surface of the inductor is not covered by the conductive material.

8. The inductor package of any of clauses 1-7, further comprising one or more connection pins, where the one or more connection pins are disposed within the least a portion of the surface of the inductor that is not covered by the conductive material.

9. The inductor package of any of clauses 1-8, where the conductive material reduces a magnetic field intensity produced by the inductor by at least 10 dB.

10. The inductor package of any of clauses 1-9, where the inductor includes at least one of a rod core or a drum core.

11. In various embodiments, a printed circuit board assembly comprises a printed circuit board (PCB) layer, and at least one inductor package fixed to the PCB layer, the inductor package including an inductor that produces a first magnetic flux, and a conductive material shielding disposed over at least a portion of a surface of the inductor that provides a reflective magnetic flux that at least partially cancels the first magnetic flux.

12. The printed circuit board assembly of clause 11, where the conductive material comprises a conductive paint applied to at least a portion of a surface of the inductor.

13. The printed circuit board assembly of clause 11 or 12, where the conductive paint comprises a conductive pigment containing at least one of silver, copper, nickel, conductive carbon, or graphite.

14. The printed circuit board assembly of any of clauses 11-13, where the conductive material comprises a conductive plating applied to at least a portion of a surface of the inductor via electroplating.

15. The printed circuit board assembly of any of clauses 11-14, where the conductive plating comprises a material containing at least one of gold, silver, copper, or nickel.

16. The printed circuit board assembly of any of clauses 11-15, further comprising at least a second inductor package fixed to the PCB layer, the second inductor package including a second inductor that produces a second magnetic flux, and a second conductive material shielding disposed over at least a portion of a surface of the second inductor that provides a second reflective magnetic flux that at least partially cancels the second magnetic flux.

17. The printed circuit board assembly of any of clauses 11-16, where the conductive material shielding is conductive plating and the second conductive material is a conductive paint.

18. The printed circuit board assembly of any of clauses 11-17, where the inductor package is included in one of an oscillator, a filter, a boost converter, or a buck converter.

19. The printed circuit board assembly of any of clauses 11-18, further comprising one or more connection pins, where a least a portion of a surface of the inductor is not covered by the conductive material, and the one or more connection pins are disposed within the least a portion of the surface of the inductor that is not covered by the conductive material.

20. The printed circuit board assembly of any of clauses 11-19, where the inductor includes at least one of a rod core or a drum core.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, apparatus, or material. Aspects of the present disclosure are described above with reference to block diagrams of apparatus (systems) and materials according to embodiments of the disclosure. While the preceding is directed to embodiments of the present disclosure, other and further embodiments of the disclosure may be devised without departing from the basic scope thereof, and the scope thereof is determined by the claims that follow.

What is claimed is:

1. An inductor package comprising:
an inductor that produces a first magnetic flux; and
a conductive material disposed on the inductor that provides a reflective magnetic flux that at least partially cancels the first magnetic flux.

2. The inductor package of claim 1, wherein the conductive material comprises a conductive paint applied to at least a portion of a surface of the inductor.

3. The inductor package of claim 2, wherein the conductive paint comprises a conductive pigment containing at least one of silver, copper, nickel, conductive carbon, or graphite.

4. The inductor package of claim 1, wherein the conductive material comprises a conductive plating applied to at least a portion of a surface of the inductor via electroplating.

5. The inductor package of claim 4, wherein the conductive plating comprises a material containing at least one of gold, silver, copper, or nickel.

6. The inductor package of claim 1, wherein the conductive material has a thickness of 5 μm to 0.2 mm on at least a portion of a surface of the inductor.

7. The inductor package of claim 1, wherein a least a portion of a surface of the inductor is not covered by the conductive material.

8. The inductor package of claim 7, further comprising one or more connection pins, wherein the one or more connection pins are disposed within the least a portion of the surface of the inductor that is not covered by the conductive material.

9. The inductor package of claim 1, wherein the conductive material reduces a magnetic field intensity produced by the inductor by at least 10 dB.

10. The inductor package of claim 1, wherein the inductor includes at least one of a rod core or a drum core.

11. A printed circuit board assembly comprising:
a printed circuit board (PCB) layer; and
at least one inductor package fixed to the PCB layer, the inductor package including:
an inductor that produces a first magnetic flux; and
a conductive material shielding disposed over at least a portion of a surface of the inductor that provides a reflective magnetic flux that at least partially cancels the first magnetic flux.

12. The printed circuit board assembly of claim 11, wherein the conductive material comprises a conductive paint applied to at least a portion of a surface of the inductor.

13. The printed circuit board assembly of claim 12, wherein the conductive paint comprises a conductive pigment containing at least one of silver, copper, nickel, conductive carbon, or graphite.

14. The printed circuit board assembly of claim 11, wherein the conductive material comprises a conductive plating applied to at least a portion of a surface of the inductor via electroplating.

15. The printed circuit board assembly of claim 14, wherein the conductive plating comprises a material containing at least one of gold, silver, copper, or nickel.

16. The printed circuit board assembly of claim 11, further comprising:
at least a second inductor package fixed to the PCB layer, the second inductor package including:
a second inductor that produces a second magnetic flux; and
a second conductive material shielding disposed over at least a portion of a surface of the second inductor that provides a second reflective magnetic flux that at least partially cancels the second magnetic flux.

17. The printed circuit board assembly of claim 16, wherein the conductive material shielding is conductive plating and the second conductive material is a conductive paint.

18. The printed circuit board assembly of claim 11, wherein the inductor package is included in one of an oscillator, a filter, a boost converter, or a buck converter.

19. The printed circuit board assembly of claim 11, further comprising one or more connection pins, wherein:
a least a portion of a surface of the inductor is not covered by the conductive material; and
the one or more connection pins are disposed within the least a portion of the surface of the inductor that is not covered by the conductive material.

20. The printed circuit board assembly of claim 11, wherein the inductor includes at least one of a rod core or a drum core.
